(19) United States
(12) Patent Application Publication
(10) Pub. No.: US 2008/0042161 A1
(43) Pub. Date: Feb. 21, 2008

(54) Nitride semiconductor light emitting diode

(75) Inventors: Jae-Woong Han, Seongnam (KR); Ji Hye Shim, Suwon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/797,492

(22) Filed: May 3, 2007

(30) Foreign Application Priority Data
Aug. 21, 2006 (KR) 10-2006-0078619

(51) Int. Cl. H01L 33/00

(52) U.S. Cl. 257/103; 257/E33.033

(57) ABSTRACT

A nitride semiconductor light emitting diode includes: an n-type clad layer; an active layer formed on the n-type clad layer; an electron blocking layer formed on the active layer, the electron blocking layer being composed of a p-type nitride semiconductor including a transition element of group III; and a p-type clad layer formed on the electron blocking layer.

### CROSS-REFERENCE TO RELATED APPLICATIONS

This application claims the benefit of Korean Patent Application No. 10-2006-0078619 filed with the Korean Intellectual Property Office on Aug. 21, 2006, the disclosure of which is incorporated herein by reference.

### BACKGROUND OF THE INVENTION

1. Field of the Invention

The present invention relates to a nitride semiconductor light emitting diode (LED) that can improve light efficiency by growing an electron blocking layer (EBL) having an excellent lattice matching with GaN.

2. Description of the Related Art

Generally, a nitride semiconductor LED is a high-power optical device that can produce full color by generating short wavelength light, such as blue light or green light. The nitride semiconductor LED is spotlighted in the related technical fields.

The nitride semiconductor LED is formed of a semiconductor single crystal having a compositional formula of Al_{y}InₓGa_{(1-x-y)}N (where, 0≦x≦1, 0≦y≦1, 0≦x+y≦1). The semiconductor single crystal can be grown on a sapphire substrate or a SiC substrate using a crystal growth process such as MOCVD (Metal Organic Chemical Vapor Deposition).

A conventional nitride semiconductor LED includes a sapphire substrate, an n-type clad layer, an active layer, and a p-type clad layer, which are sequentially formed on the sapphire substrate. In addition, the conventional nitride semiconductor LED includes a negative electrode (n-electrode) connected to the n-type clad layer and a positive electrode (p-electrode) connected to the p-type clad layer. The active layer may have a multi-quantum well (MQW) structure in which a GaN quantum barrier layer and an InGaN quantum well layer are alternately formed several times.

When a predetermined current is applied to the electrodes, electrons provided from the n-type clad layer and holes provided from the p-type clad layer are recombined in the active layer of the multi-quantum well structure to emit short wavelength light, such as green light or blue light.

An electron blocking layer (EBL) is formed between the active layer and the p-type clad layer. The electron blocking layer is composed of an aluminum-contained nitride semiconductor material, such as p-type AlGaN, which has an energy bandgap greater than that of the p-type clad layer.

FIG. 1 is an energy bandgap diagram of a conventional nitride semiconductor LED having an electron blocking layer composed of p-type AlGaN.

As shown in FIG. 1, since the electron blocking layer (EBL) composed of p-type AlGaN has the energy bandgap greater than that of the p-type clad layer, electrons provided from the n-type clad layer can be effectively prevented from overflowing without being recombined in the active layer of the multi-quantum well structure. Therefore, the electron blocking layer can enhance the light efficiency of the LED by reducing electrons consumed due to the overflowing.

However, since AlGaN has a lattice constant different from that of GaN, it may not match with GaN during growth and may be deformed. Thus, it is difficult to obtain the electron blocking layer with an excellent quality.

Therefore, instead of AlGaN, AlInGaN is used as the electron blocking layer. AlInGaN can be grown as a layer having an energy bandgap greater than that of GaN and having a lattice constant equal to that of GaN.

The AlInGaN layer can be grown using AlGaN and InGaN. However, AlGaN must be grown at a temperature higher than 1,000° C. so as to obtain good crystalline quality. In addition, InGaN must be grown at a temperature ranging from 700° C. to 800° C. because a bonding force of InN is weak. Thus, it is very difficult to obtain the AlInGaN layer with an excellent quality.

Therefore, there is a need for a new nitride semiconductor LED that can maximize the light efficiency by providing an electron blocking layer having an excellent lattice matching with GaN.

### SUMMARY OF THE INVENTION

An advantage of the present invention is that it provides a nitride semiconductor LED that can provide an electron blocking layer having an excellent lattice matching with GaN, thereby maximizing the light efficiency of the LED.

Additional aspect and advantages of the present general inventive concept will be set forth in part in the description which follows and, in part, will be obvious from the description, or may be learned by practice of the general inventive concept.

According to an aspect of the invention, a nitride semiconductor LED includes: an n-type clad layer; an active layer formed on the n-type clad layer; an electron blocking layer formed on the active layer, the electron blocking layer being composed of a p-type nitride semiconductor including a transition element of group III; and a p-type clad layer formed on the electron blocking layer.

According to another aspect of the present invention, the electron blocking layer is formed of p-type AlYGaN.

According to a further aspect of the present invention, a nitride semiconductor LED includes: a substrate; an n-type clad layer formed on the substrate; an active layer formed on a portion of the n-type clad layer; an electron blocking layer formed on the active layer, the electron blocking layer being composed of a p-type nitride semiconductor including a transition element of group III; a p-type clad layer formed on the electron blocking layer; a p-electrode formed on the p-type clad layer; and an n-electrode formed on the n-type clad layer where the active layer is not formed.

According to a sill further aspect of the present invention, the electron blocking layer is formed of p-type AlYGaN.

According to a further aspect of the present invention, a nitride semiconductor LED includes: a structure support layer; a p-type electrode formed on the structure support layer; a p-type clad layer formed on the p-type electrode; an electron blocking layer formed on the p-type clad layer, the electron blocking layer being composed of a p-type nitride semiconductor including a transition element of group 3; an active layer formed on the electron blocking layer; an n-type clad layer formed on the active layer; and an n-electrode formed on the n-type clad layer.

According to a further aspect of the present invention, the electron blocking layer is formed of p-type AlYGaN.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is an energy band diagram of a conventional nitride semiconductor LED having an electron blocking layer composed of p-type AlGaN;

FIG. 2 is a sectional view of a nitride semiconductor LED according to a first embodiment of the present invention;

FIG. 3 is an energy band diagram of a nitride semiconductor LED having an electron block layer formed of p-type AlYGaN according to the invention;

FIG. 4 is a graph showing a bandgap energy and a lattice constant for each compound; and

FIG. 5 is a sectional view of a nitride semiconductor LED according to a second embodiment of the invention.

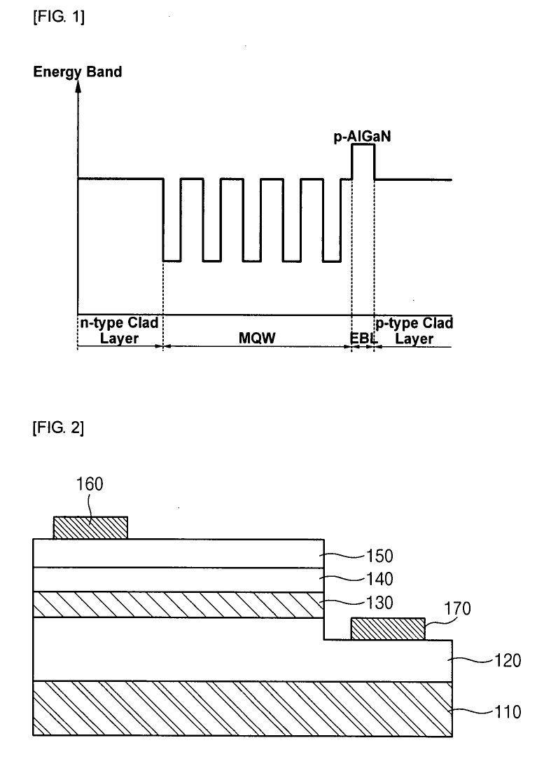

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures. In the drawings, the thicknesses of layers and regions are exaggerated for clarity.

Hereinafter, nitride semiconductor LEDs according to embodiments of the present invention will be described in detail with reference to the accompanying drawings.

### First Embodiment

A nitride semiconductor LED according to a first embodiment of the present invention will be described below in detail with reference to FIGS. 2 to 4.

FIG. 2 is a sectional view of a nitride semiconductor LED according to a first embodiment of the present invention. In FIG. 2, a lateral nitride semiconductor LED is provided for illustrative purposes.

Referring to FIG. 2, the nitride semiconductor LED includes a substrate 110, an n-type clad layer 120, an active layer 130, and a p-type clad layer 150, which are sequentially formed on the substrate 110.

Preferably, the substrate 110 is formed of a transparent material containing sapphire. In addition to sapphire, the substrate 110 may be formed of zinc oxide (ZnO), gallium nitride (GaN), silicon carbide (SiC), or aluminum nitride (AlN).

A buffer layer (not shown) may be formed between the substrate 110 and the n-type clad layer 120 so as to enhance lattice matching therebetween. The buffer layer may be formed of GaN or AlN/GaN.

The n-type and p-type clad layers 120 and 150 and the active layer 130 can be formed of a semiconductor material having a compositional formula of Al_{y}InₓGa_{(1-x-y)}N (where, 0≦x≦1, 0≦y≦1, 0≦x+y≦1).

More specifically, the n-type clad layer 120 can be formed of a GaN layer doped with n-type conductive impurities. For example, the n-type conductive impurities may be Si, Ge, Sn and the like, among which Si is preferably used. Further, the p-type clad layer 150 can be formed of a GaN layer doped with p-type conductive impurities. For example, the p-type conductive impurities may be Mg, Zn, Be and the like, among which Mg is preferably used. The active layer 130 can be formed of an InGaN/GaN layer with a multi-quantum well structure.

Portions of the p-type clad layer 150 and the active layer 130 are removed by mesa-etching such that a portion of the n-type clad layer 120 is exposed.

A p-electrode 260 is formed on the p-type clad layer 150.

An n-electrode 270 is formed on the n-type clad layer 120 exposed by mesa-etching, where the active layer 130 is not formed.

In such a nitride semiconductor LED according to the present invention, the electron blocking layer 140 having an energy bandgap greater than that of the p-type clad layer 150 is formed between the active layer 130 and the p-type clad layer 150.

Particularly, the electron blocking layer 140 may be formed of a p-type semiconductor (e.g., p-type AlYGaN) including a transition element of group III.

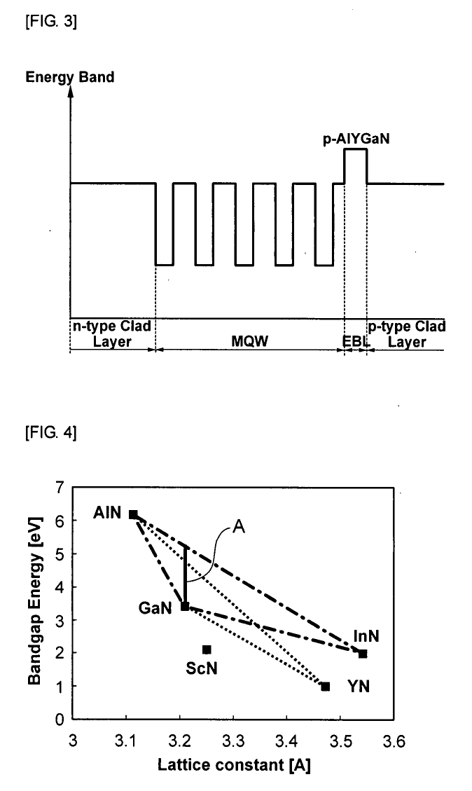

FIG. 3 is an energy band diagram of the nitride semiconductor LED having the electron block layer formed of p-type AlYGaN according to the present invention.

As shown in FIG. 3, like the conventional electron blocking layer formed of p-type AlGaN, the electron blocking layer formed of p-type AlYGaN has an energy bandgap greater than that of the p-type clad layer. Thus, electrons provided from the n-type clad layer can be effectively prevented from overflowing into the p-type clad layer without being recombined in the active layer of the multi-quantum well structure. Therefore, the electron blocking layer can enhance the light efficiency of the LED by reducing electrons consumed due to the overflowing.

FIG. 4 is a graph showing a bandgap energy and a lattice constant for each compound. In FIG. 4, a triangle indicated by a dashed dotted line represents an AlInGaN system that is a material for the conventional electron blocking layer, and a triangle indicated by a dotted line represents an AlYGaN system that is a material for the electron blocking layer according to the present invention.

In growing the electron blocking layer 140, compounds included in a range indicated by a solid line A must be used so as to prevent the degradation in LED characteristic due to a difference in lattice constant. Specifically, the compounds have an energy bandgap greater than that of GaN and a lattice constant equal to that of GaN.

As described above, in growing the conventional AlInGaN layer, GaN must be grown at a temperature higher than 1,000° C. and InGaN must be grown at a temperature ranging from 700° C. to 800° C. so as to obtain excellent crystalline quality. Thus, it is difficult to obtain the AlInGaN layer with an excellent quality because the growth temperatures of materials used for growing the AlInGaN layer are different from each other.

However, according to the present invention, the electron blocking layer 140 with an excellent quality can be formed by growing p-type AlYGaN, instead of InGaN that is difficult to grow at a temperature higher than 1,000° C., which is the growth temperature of AlGaN, due to a weak bonding force of InN. The p-type AlYGaN includes AlGaN and YGaN containing group III element (e.g., Y (yttrium)) that can be grown at a temperature higher than 1,000° C. because of its high melting point and strong bonding force.

The AlYGaN system indicated by the dotted triangle in FIG. 4 can be grown under the condition, indicated by the solid line A, where its bandgap energy is greater than that of GaN and its lattice constant is equal to that of GaN. In addition, the AlYGaN layer with an excellent quality can be obtained by growing YGaN together with AlGaN at a temperature higher than 1,000° C. The electron blocking layer 140 formed of the AlYGaN layer can maximize the light efficiency.

The transition element of the group III, which can be grown at a temperature higher than 1,000° C., includes Sc (Scandium) as well as Y. The p-type AlScGaN layer with an excellent quality can be grown using ScGaN instead of InGaN. In the case of the AlScGaN system, however, the region where the bandgap energy is greater than that of GaN and the lattice constant is equal to that of GaN cannot be found because AlN, GaN and ScN are placed on a substantially straight line, as shown in FIG. 4. Thus, the AlScGaN layer is not appropriate for the electron blocking layer.

As descried above, the electron blocking layer 140 having an excellent lattice matching with GaN and excellent crystalline quality can be formed using AlYGaN, instead of AlGaN or AlInGaN. Consequently, the present invention can further enhance device characteristics, such as the light efficiency of the LED.

### Second Embodiment

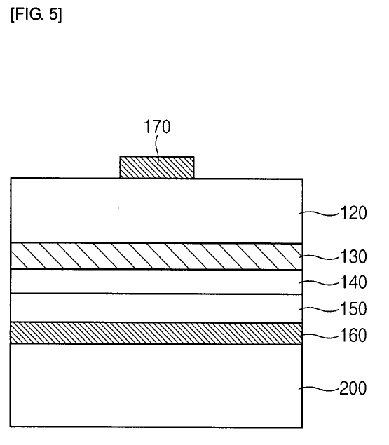

A nitride semiconductor LED according to a second embodiment of the present invention will be described below in detail with reference to FIG. 5.

FIG. 5 is a sectional view of a nitride semiconductor LED according to a second embodiment of the present invention. In FIG. 5, a vertical nitride semiconductor LED is provided for illustrative purposes.

Referring to FIG. 5, the nitride semiconductor LED includes a structure support layer 200 at the lowermost portion thereof.

The structure support layer 200 serves as a support layer of the LED and an electrode and may be formed of a Si substrate, a GaAs substrate, a Ge substrate, or a metal layer.

A p-electrode 160 is formed on the structure support layer 200. Preferably, the p-electrode 160 is formed of metal with high reflectance so as to serve as an electrode and a reflecting layer at the same time.

A p-type clad layer 150, an electron blocking layer 140, an active layer 130, and an n-type clad layer 120 are sequentially formed on the p-type electrode 160. An n-electrode 170 is formed on the n-type clad layer 120.

The p-type clad layer 150 can be formed of a GaN layer doped with p-type conductive impurities. The active layer 130 can be formed of an InGaN/GaN layer with a multi-quantum well structure. The n-type clad layer 120 can be formed of a GaN layer doped with n-type conductive impurities.

The electron blocking layer 140 can effectively prevent the electrons provided from the n-type clad layer 120 from overflowing into the p-type clad layer 150 without being recombined in the active layer 130 with the multi-quantum well structure. The electron blocking layer 140 is formed of a nitride semiconductor material having an energy bandgap greater than that of the p-type clad layer 150.

Specifically, the electron blocking layer 140 is formed of a p-type nitride semiconductor (e.g., p-type AlYGaN) including a transition element of group III.

P-type AlYGaN can be obtained by growing YGaN and AlGaN including Y (yttrium) that can be grown at a temperature higher than 1,000° C. because of its high melting point and its strong bonding force. At this point, the AlYGaN layer with an excellent quality can be easily obtained because YGaN and AlGaN have a similar growth temperature for excellent crystalline quality.

Like the first embodiment, the second embodiment can form the electron blocking layer with an excellent quality by growing it using p-type AlYGaN having an excellent lattice matching with GaN. Thus, the second embodiment can obtain the same operation and effect as those of the first embodiment.

According to the present invention, the electron blocking layer disposed between the active layer and the p-type clad layer is formed using AlYGaN, instead of AlGaN or AlInGaN. Therefore, the electron blocking layer can be formed to have an excellent lattice matching with GaN and an excellent crystalline quality.

Consequently, the present invention can further enhance the device characteristics, such as the light efficiency of the LED.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A nitride semiconductor light emitting diode (LED) comprising:
an n-type clad layer;
an active layer formed on the n-type clad layer;
an electron blocking layer formed on the active layer, the electron blocking layer being composed of a p-type nitride semiconductor including a transition element of group III; and
a p-type clad layer formed on the electron blocking layer.

2. The nitride semiconductor LED according to claim 1,
wherein the electron blocking layer is formed of p-type AlYGaN.

3. A nitride semiconductor light emitting diode (LED) comprising:
a substrate;
an n-type clad layer formed on the substrate;
an active layer formed on a portion of the n-type clad layer;
an electron blocking layer formed on the active layer, the electron blocking layer being composed of a p-type nitride semiconductor including a transition element of group III;
a p-type clad layer formed on the electron blocking layer;
a p-electrode formed on the p-type clad layer; and
an n-electrode formed on the n-type clad layer where the active layer is not formed.

4. The nitride semiconductor LED according to claim 3,
wherein the electron blocking layer is formed of p-type AlYGaN.

5. A nitride semiconductor light emitting diode (LED) comprising:
a structure support layer;
a p-type electrode formed on the structure support layer;
a p-type clad layer formed on the p-type electrode;
an electron blocking layer formed on the p-type clad layer, the electron blocking layer being composed of a p-type nitride semiconductor including a transition element of group III;
an active layer formed on the electron blocking layer;
an n-type clad layer formed on the active layer; and
an n-electrode formed on the n-type clad layer.

6. The nitride semiconductor LED according to claim 5,
wherein the electron blocking layer is formed of p-type AlYGaN.
